(19) United States
(12) Patent Application Publication
(10) Pub. No.: US 2003/0056724 A1
(43) Pub. Date: Mar. 27, 2003

(54) Manufacturing device for substrate with transparent conductive film

(76) Inventor: Shunji Wada, Osaka (JP)

Correspondence Address: Frishauf Holtz Goodman & Chick, 767 Third Avenue 25th Floor, New York, NY, 10017-2023, US

(21) Appl. No.: 10/149,728

(22) PCT Filed: Oct. 17, 2001
(86) PCT No.: PCT/JP01/09116

(30) Foreign Application Priority Data
Oct. 18, 2000 (JP) 2000-318410

(51) Int. Cl. C23C 16/00

(52) U.S. Cl. 118/500; 118/715; 118/729; 118/728

(57) ABSTRACT

There is provided an apparatus for manufacturing substrates with transparent conductive films, which is capable of preventing occurrence of abnormal discharge and making feed rollers thereof durable. A carrier supports a tray holding an insulated substrate via support members each formed by a hollow cylindrical member (separator element) and a hollow cylindrical member (support element). The carrier is transported by feed rollers 38 whose axles are not made of a ceramic material but made of a metal higher in rigidity, in an atmosphere of vaporized particles of an ITO sintered body. The hollow cylindrical members (separators) separate the atmosphere of vaporized particles from outer surfaces of the hollow cylindrical members (support elements) to form a labyrinth in a path of migration and attachment of the vaporized particles.

### TECHNICAL FIELD

This invention relates to an apparatus for manufacturing substrates with transparent conductive films, and more particularly to an apparatus for forming a transparent conductive film on a substrate under vacuum by using a plasma.

### BACKGROUND ART

Conventionally, in the manufacture of liquid crystal display elements, organic EL display elements, and the like, transparent conductive films, such as ITO films, or transparent non-conductive films, such as SiO₂ films and TiO₂ films, are formed by substrate-manufacturing apparatuses implementing the method of forming a film by using a plasma, which is typified by a sputtering method and an ion plating method.

The conventional substrate-manufacturing apparatuses include an ion plating apparatus that forms an ITO film on an insulated substrate by feeding the insulated substrate in an atmosphere of particles of ITO vaporized from an ITO sintered body and ionized by a plasma beam, by using a film-forming jig 900 in which the insulated substrate is fixedly arranged and feed rollers 1000 as shown in FIGS. 9 to 12, as described in detail hereinbelow.

FIG. 9 is a perspective view of a film-forming jig for an insulated substrate used in the conventional ion plating apparatus.

As shown in FIG. 9, the film-forming jig 900 for an insulated substrate is comprised of a tray 902 for holding the insulated substrate 901, and a carrier 903 that carries the tray 902 thereon.

The tray 902 is formed by a box-shaped member having a rectangular opening 902b formed at a bottom 902a thereof, and two pairs of protrusions 902d extending laterally outward from opposite sides of an upper brim 902c thereof. The tray 902 holds the insulated substrate 901 at the bottom 902a of the box-shaped member.

Further, the carrier 903 is formed by a frame member which receives the tray 902 therein, and holds the tray 902d by the protrusions 902d of the tray 902d resting thereon.

The film-forming jig 900 constructed as above is transported with the insulated substrate 901 held thereon, in the atmosphere of particles of ITO vaporized from the ITO sintered body by means of the feed rollers 1000 appearing in FIGS. 10 and 11 in a feeding direction indicated by an arrow A in FIG. 10, whereby an ITO film is formed on the insulated substrate 901.

FIG. 10 is a plan view schematically showing the arrangement of the film-forming jig 900 and the feed rollers 1000 shown in FIG. 9, and FIG. 11 is a cross-sectional view taken on line XI-XI of FIG. 10.

In FIGS. 10 and 11, a plurality of pairs of feed rollers 1000 arranged in the feeding direction A as indicated in FIG. 10 are placed in the atmosphere of vaporized ITO particles within the ion plating apparatus, not shown. Arranged on the feed rollers 1000 is the carrier 903 that carries the tray 902 thereon, which is transported in the feeding direction A as shown in FIG. 10, by rotation of the feed rollers.

The ion plating apparatus constructed above forms a transparent conductive film, such as an ITO film, on the insulated substrate 901 typically by using a plasma. However, the tray 902 with which the insulated substrate 901 is in contact is electrically conductive, and therefore, an abnormal discharge can occur from the insulated substrate 901 to the tray 902.

The abnormal discharge is caused when the insulated substrate 901 which is electrically charged by electric charges existing in the plasma atmosphere, and a conductive material (component(s) of the film-forming jig 900, such as the tray 902 which is at an earth potential, or the like) having a potential difference with respect to the insulated substrate 901 are brought into contact, causing a discharge of the electric charges on the insulated substrate 901 to the component(s) of the film-forming jig 900, such as the tray 902, or the like.

In the abnormal discharge, the electric charges on the insulated substrate 901 are instantaneously discharged in an instantaneous flow of a very large current, so that a mark can be formed on the insulated substrate 901 by the impulse of the discharge and part of the conductive material can be scattered by evaporation, causing inconveniences such as the problem that the scattered part of the conductive material is attached to the insulated substrate 901.

For instance, in the film-forming jig 900 in FIG. 9, a portion of the insulated substrate 901 in contact with the tray 902 may be damaged, and portions of the tray 902, the carrier 903 or the feed rollers 1000 may be scattered by evaporation and attached to the insulated substrate 901. As a result, in the latter stage of the process for forming the transparent conductive film, there may occur the problem of the insulated substrate 901 being cracked and a foreign matter being attached to the insulated substrate 901.

To prevent the insulated substrate 901 from being cracked or a foreign matter from being attached thereto due to the above described abnormal discharge, the film-forming jig 900 in contact with the insulated substrate 901 needs to be at the same potential as that of the insulated substrate 901. To this end, it is only required that the film-forming jig 900 is electrically floated from the body of the ion plating apparatus, and conventionally, as shown in FIG. 12, the electrical floating of the film-forming jig 900 from the ion plating apparatus body is effected by using a non-conductive ceramic axle 1200 as the axle of each of the feed rollers 1000.

However, the ceramic axle 1200 undergoes loads of the insulated substrate 901 and the film-forming jig 900 and torque by the rotation of the feed roller 1000, so that the ceramic axle 1200 may be broken to disable the feeding of the film-forming jig 900 or cause trouble in feeding the film-forming jig 900.

It is an object of the present invention to provide an apparatus for manufacturing substrates with transparent conductive films, which is capable of preventing occurrence of abnormal discharge and making feed rollers thereof durable.

### DISCLOSURE OF INVENTION

To attain the above object, according to the present invention, there is provided an apparatus for manufacturing a substrate with a transparent conductive film, comprising a holding member for holding an insulated substrate, first carrier means for supporting the holding member, feeding means for feeding the first carrier means, and second carrier means having at least one support element arranged on the first carrier member, and at least one separator element arranged on the first carrier member and extending along the support element, wherein the first carrier member supports the holding member via the second carrier member, and the separator element forms together with the support element a labyrinth in a path of migration and attachment of vaporized particles for forming the transparent conductive film to a surface of the support element.

According to this apparatus, the separator element of the second carrier member forms together with the support element of the same a labyrinth in a path of migration and attachment of vaporized particles for forming the transparent conductive film to a surface of the support element. Therefore, the transparent conductive film is not continuously formed from the insulated substrate to the feeding means, and hence the insulated substrate can be maintained in a stable floated state to prevent the occurrence of an abnormal discharge. Further, the axles of the feeding means are no longer required to be formed of a ceramic material, but can be formed of a metal higher in rigidity, and hence it is possible to make the feeding means durable.

In a preferred form of the present invention, there is provided an apparatus for manufacturing a substrate with a transparent conductive film, comprising a holding member for holding an insulated substrate, first carrier means for supporting the holding member, feeding means for feeding the first carrier means, and second carrier means having at least one support element arranged on the first carrier member, and at least one separator element arranged on the first carrier member and extending along the support element, wherein the first carrier member supports the holding member via the support element of the second carrier means, and the separator element is lower in height than the support element such that the separator element partially separates the support element from an atmosphere of vaporized particles for forming the transparent conductive film within the apparatus.

According to this apparatus, the separator element partially separates the support element from the atmosphere of vaporized particles within the apparatus, which makes it possible to form a labyrinth in a path of migration and attachment of the vaporized particles to a surface of the support element. As a result, the transparent conductive film is not continuously formed from the insulated substrate to the feeding means, and hence the insulated substrate can be maintained in a stable floated state to prevent the occurrence of an abnormal discharge. Further, the axles of the feeding means are no longer required to be formed of a ceramic material, but can be formed of a metal higher in rigidity, and hence it is possible to make the feeding means durable.

Preferably, in a right-angled triangle defined by a first side on the first carrier means, the first side corresponding to a distance between a surface of the support element facing toward the separator element and a surface of the separator element facing toward the support element, and a second side on the surface of the separator element corresponding to a height of the separator element, with the first side and the second side intersecting at right angles, an angle formed by a hypotenuse of the right-angled triangle and the first side is within a range of 45 to 85°.

According to this preferred embodiment, the angle formed between a hypotenuse of a right-angled triangle defined by the first side and the second side with the first and second sides intersecting at right angles is within a range of 45 to 85°. Therefore, the distance between the opposed surfaces of the support member and the separator member can be reduced, whereby it can be made difficult for the vaporized particles to migrate to the support member, so that it is possible to positively prevent the transparent conductive film from being continuously formed from the insulated substrate to the feeding means.

More preferably, the angle is within a range of 60 to 85°.

According to this preferred embodiment, it is possible to more positively prevent the transparent conductive film from being continuously formed from the insulated substrate to the feeding means.

Preferably, a difference in height between the support element and the separator element is within a range of 1 to 5 mm.

According to this preferred embodiment, the difference in height between the support element and the separator element is within a range of 1 to 5 mm. Therefore, it is difficult for the vaporized particles to migrate to the support member, so that it is possible to effectively prevent the transparent conductive film from being continuously formed from the insulated substrate to the feeding means.

More preferably, the difference in height is within a range of 1 to 3 mm.

According to this preferred embodiment, it is possible to more effectively prevent the transparent conductive film from being continuously formed from the insulated substrate to the feeding means.

Preferably, the second carrier means is made of a ceramic material.

According to this preferred embodiment, the second carrier means is made of a ceramic material. Therefore, the insulated substrate can be maintained in a stable floated state to prevent the occurrence of an abnormal discharge.

Preferably, the support element and the separator element each comprise a hollow cylindrical member.

According to this preferred embodiment, the support element and the separator element each comprise a hollow cylindrical member. Therefore, the support element and the separator element can be manufactured easily, and further when the separator element and the support element are arranged on the first carrier means, it is not necessary to take the orientation of the support member and that of the separator member into account.

Preferably, the second carrier means comprises a plurality of pairs of the support element and the separator element arranged on the first carrier means.

Preferably, the support element and the separator element comprise boards arranged on the first carrier means.

In this case, it is preferred that the boards extend along a whole length of an associated side of the holding member.

Preferably, the apparatus further comprises an additional separator element formed on the holding member as a flange-like member.

The above and other objects, features and advantages of the present invention will be made more apparent from the following detailed description taken in conjunction with the accompanying drawings.

### BRIEF DESCRIPTION OF DRAWINGS

FIG. 1 is a diagram schematically showing the arrangement of an apparatus for manufacturing a transparent conductive film, according to an embodiment of the present invention;

FIG. 2 is a perspective view of a film-forming jig appearing in FIG. 1;

FIG. 3 is a cross-sectional view taken on line III-III in FIG. 2;

FIG. 4 is a perspective view of support members appearing in FIG. 3;

FIG. 5 is a cross-sectional view taken on line V-V in FIG. 4;

FIG. 6 is a diagram useful in explaining a process of forming an ITO film by the apparatus for manufacturing a transparent conductive film;

FIG. 7 is a view showing a variation of the support members;

FIG. 8 is a view showing a variation of a tray;

FIG. 9 is a perspective view showing a film-forming jig for an insulated substrate, employed in a conventional ion plating apparatus;

FIG. 10 is a plan view schematically showing the arrangement of the film-forming jig in FIG. 9 and feed rollers;

FIG. 11 is a cross-sectional view taken on line XI-XI in FIG. 10; and

FIG. 12 is a diagram schematically showing the configuration of means for electrical floating, employed in the conventional ion plating apparatus.

### BEST MODE FOR CARRYING OUT THE INVENTION

The present invention will be described in detail with reference to the drawings showing an embodiment thereof.

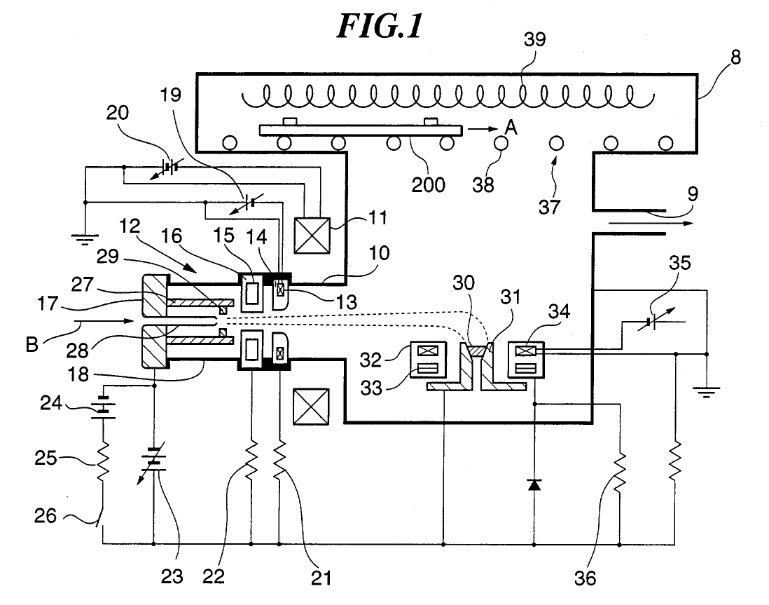

Referring first to FIG. 1, there is schematically shown the arrangement of an apparatus for manufacturing a substrate with a transparent conductive film, according to an embodiment of the present invention. The apparatus according to the present embodiment is an ion plating apparatus.

As shown in FIG. 1, the ion plating apparatus includes a vacuum container 8 as a film-forming chamber, which has one side wall formed with a discharge port 9, and an opposite side wall formed with a hollow cylindrical portion 10. The hollow cylindrical portion 10 has a plasma gun 12 of a pressure-gradient type mounted therein, and a focusing coil 11 arranged therearound.

The plasma gun 12 is comprised of a first intermediate electrode 14 containing an electromagnetic coil 13 and secured to a wall of the hollow cylindrical portion 10, a second intermediate electrode 16 containing an annular permanent magnet 15 and arranged in parallel with the first intermediate electrode 14, a cathode 17, and a glass tube 18 interposed between the cathode 17 and the second intermediate electrode 16.

The electromagnetic coil 13 is excited by a power supply 19 and the focusing coil 11 is excited by a power supply 20. It should be noted that the power supplies 19 and 12 are both a variable regulated type.

The first and second intermediate electrodes 14, 16 are connected via respective voltage-dropping resistors 21, 22 to one end (anode side) of a variable regulated voltage main power supply 23 which has the other end (cathode side) thereof connected to the cathode 17. Further, the main power supply 23 is in parallel connection via a switch 26 with an auxiliary discharge power supply 24 and a voltage-dropping resistor 25 connected in series.

Further, the glass tube 18 contains a hollow cylindrical member 27 formed of molybdenum (Mo) and secured to the cathode 17, a pipe 28 formed of tantalum (Ta) and extending through the cathode 17, and an annular member 29 formed of LaB₆ and arranged at a location in the vicinity of an inner end of the pipe 28 in a manner secured to the inner wall of the hollow cylindrical member 27. A discharge gas (e.g. argon gas having a predetermined oxygen content) is supplied to the inside of the plasma gun 12 via the pipe 28 from a direction indicated by an arrow B.

At the bottom of the vacuum container 8, there is arranged a main hearth 31 that receives an ITO sintered body 30 as a tablet (material to be vaporized) therein, and an auxiliary hearth 31 is provided around the main hearth 31. The main hearth 31 is formed of an electrically-conductive material having an excellent thermal conductivity, e.g. copper, and formed with a recess for receiving a plasma beam from the plasma gun 12. The main hearth 31 is connected to the anode of the main power supply 23 to form an anode which attracts the plasma beam.

The auxiliary hearth 32 is made of an electrically-conductive material having an excellent thermal conductivity similarly to the main hearth 31, and contains an annular permanent magnet 33 and an electromagnet 34. The electromagnet 34 is excited by a hearth coil power supply 35 of a variable regulated type. That is, the auxiliary hearth 32 is constructed such that the annular permanent magnet 33 and the electromagnet 34 are coaxially laminated within an annular container 32a which surrounds the main hearth 31, and at the same time the electromagnet 34 is connected to the hearth coil power supply 35, for generation of a magnetic field such that the magnetic field generated by the electromagnet 34 and a magnetic field generated by the annular permanent magnet 33 overlap each other. In this case, the direction of the inner magnetic flux of the magnetic field generated by the annular permanent magnet 33 and that of the inner magnetic flux of the magnetic field generated by the electromagnet 34 are the same, and the current supplied to the electromagnet 34 is varied by varying the voltage of the hearth coil power supply 35.

Further, similarly to the main hearth 31, the auxiliary hearth 32 is also connected to the anode of the main power supply 23 via a voltage-dropping resistor 36 to form an anode.

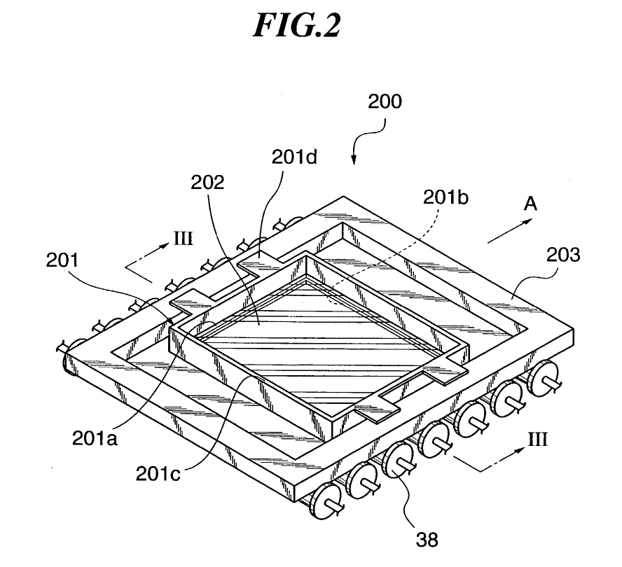

In the present embodiment, in an upper portion of the vacuum container 8, there is arranged a feed roller group 37 for feeding a film-forming jig 200, described in detail hereinafter with reference to FIG. 2, that holds an insulated substrate, in a direction indicated by an arrow A in FIG. 1. The feed roller group 37 is comprised of a plurality of feed rollers (feeding means) 38 horizontally juxtaposed (see FIG. 2). Each feed roller 38 has an axle not made of a ceramic material but made of a metal having a higher rigidity than the ceramic material. Further, in the upper portion of the vacuum container 8, there is arranged a heater 39 for heating the insulated substrate to a predetermined temperature.

In the ion-plating apparatus thus constructed, an ITO sintered body 30 having a SnO₂ content within a range of 4 to 6 mass % is received in the recess of the main hearth 31, and the discharge gas is supplied from the cathode 17 side of the plasma gun 12 through the pipe 28 into the chamber 8. This causes an electric discharge to occur between the pipe 28 and the main hearth 31 to thereby generate a plasma beam. The plasma beam is focused by the actions of the annular permanent magnet 15 and the electromagnet 13, and guided by the magnetic field determined by the focusing coil 11 and the annular permanent magnet 33 and the electromagnet 34 within the auxiliary hearth 32, to reach the main hearth 31.

The ITO sintered body 30 received within the main hearth 31 is heated by the plasma beam, for vaporization, and the vaporized ITO particles are ionized by the plasma beam and attached to the insulated substrate heated by the heater 39 to form an ITO film thereon.

Next, the film-forming jig 200 appearing in FIG. 1 will be described in detail.

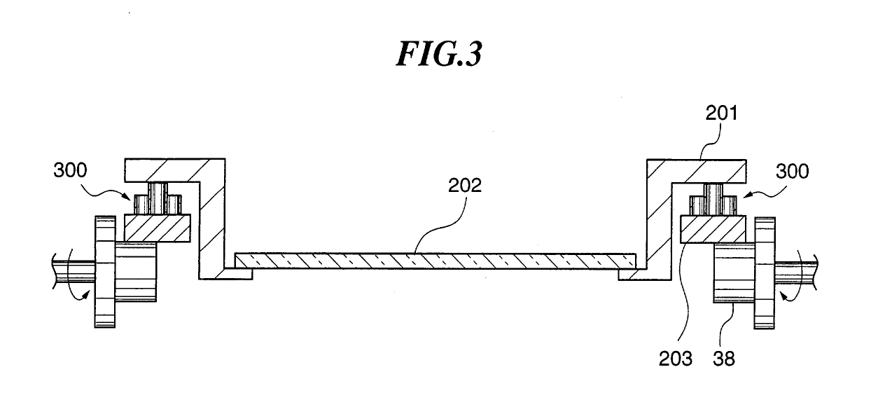

FIG. 2 is a perspective view of the film-forming jig 200, while FIG. 3 is a cross-sectional view taken on line III-III in FIG. 2.

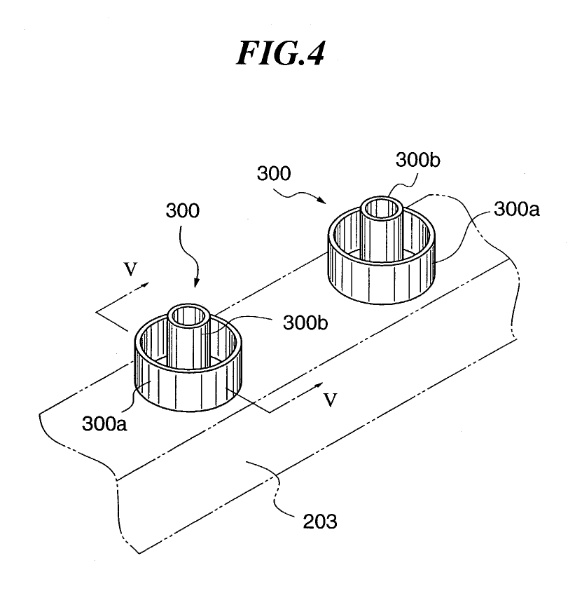

As shown in FIGS. 2 and 3, the film-forming jig 200 is comprised of a tray (holding member) 201 for holding the insulated substrate 202, and a carrier (first carrier means) 203 that carries the tray 201 thereon via a plurality of (four in the illustrated embodiment) support members 300 (second carrier means). The support members 300 will de described hereinafter with reference to FIG. 4.

The tray 201 is formed by a box-shaped member having a rectangular opening 201b formed at a bottom 201a thereof, and two pairs of protrusions 201d extending laterally outward from opposite sides of an upper brim 201c thereof. The tray 201 holds the insulated substrate 202 at the bottom 201a of the box-shaped member. The ITO particles vaporized from the ITO sintered body 30 are attached to the insulated substrate 20 exposed to the outside via the above opening.

The carrier 203 is formed by a frame member made of a metal or the like which receives the tray 201 therein, and holds the tray 201 via the support members 300 by the protrusions 201d of the tray 201 resting thereon.

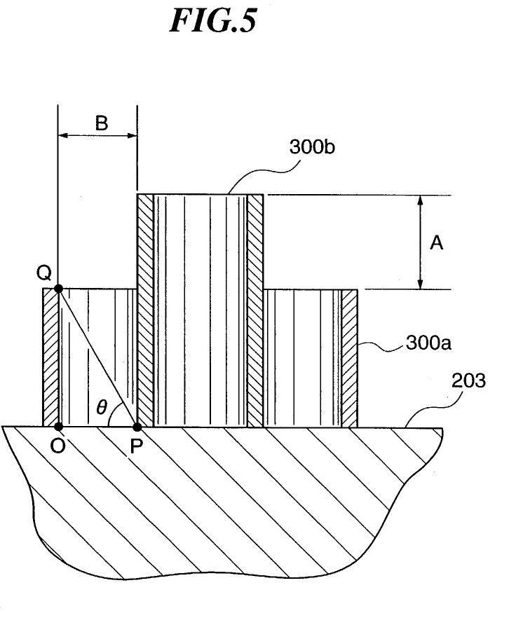

FIG. 4 is a perspective view of the support members 300 in FIG. 3, while FIG. 5 is a cross-sectional view taken on line V-V in FIG. 4.

As shown in FIGS. 4 and 5, the support members 300 are juxtaposed on the carrier 203. Each support member 300 is comprised of a hollow cylindrical member (separator element) 300a made of a ceramic material erected on the carrier 203, and a hollow cylindrical member (support element) 300b coaxially received in the hollow cylindrical member 300a and erected on the carrier 203 (FIG. 4). In short, each corresponding pair of the hollow cylindrical members 300a and 300b has a nested configuration.

As shown in FIG. 5, the height of the hollow cylindrical member 300b is greater than that of the hollow cylindrical member 300a by a difference A in length therebetween, and therefore, the tray 201 is supported only by the hollow cylindrical member 300b. Therefore, the hollow cylindrical members 300b are in direct contact with the protrusions 201d, but the hollow cylindrical members 300a are not in contact with the protrusions 201d, so that a labyrinth, referred to hereinafter, is formed between the hollow cylindrical members 300a and the hollow cylindrical members 300b. Symbol B in the figure indicates the difference between one half of the inner diameter of the hollow cylindrical member 300a and one half of the outer diameter of the hollow cylindrical member 300b.

tThe difference A between the height of the hollow cylindrical member 300b and that of the hollow cylindrical member 300a is preferably within a range of 1 to 5 mm, and more preferably within a range of 1 to 3 mm. Further, in a right-angled triangle defined by a side OP (first side) corresponding to the difference B between one half of the inner diameter of the hollow cylindrical member 300a and one half of the outer diameter of the hollow cylindrical member 300b, and a side OQ (second side) corresponding to the height of the hollow cylindrical member 300a, with the sides OP and OQ intersecting at right angles, assuming that an angle formed by the side OP and a hypotenuse PQ is represented by θ, the angle θ is preferably within a range of 45 to 85°, more preferably within a range of 60 to 85°. The difference A between the height of the hollow cylindrical member 300b and that of the hollow cylindrical member 300a and the difference B between the half of the inner diameter of the hollow cylindrical member 300a and that of the outer diameter of the hollow cylindrical member 300b are preferably set to as small values as possible.

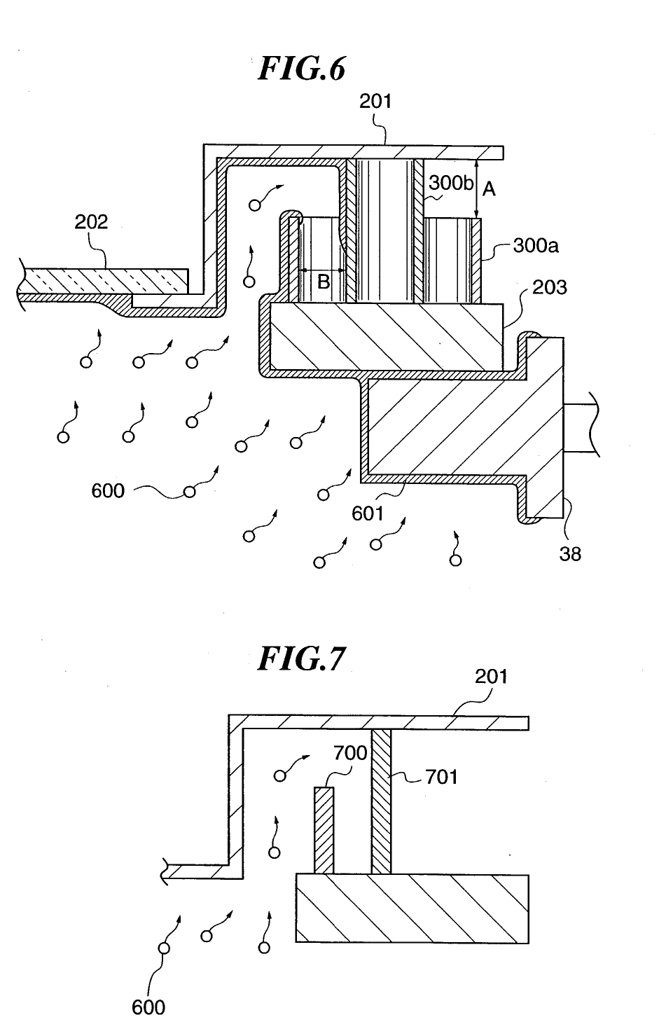

FIG. 6 shows a process of forming an ITO film by the FIG. 1 apparatus.

As shown in FIG. 6, vaporized particles 600 vaporized from the ITO sintered body 30 received within the main hearth 31 by heating by means of the plasma beam are attached to surfaces of the insulated substrate 202, the tray 201, the carrier 203, and the feed rollers 38, which surfaces are exposed to the atmosphere of the vaporized particles 600 as well as outer surfaces of the hollow cylindrical members 300a and 300b, to form an ITO film 601.

In the present embodiment, the aforementioned labyrinth is formed in a path of migration and attachment of the vaporized particles 600 to an outer surface of the hollow cylindrical members 300b, by the hollow cylindrical members 300a which separate the outer surfaces of the hollow cylindrical members 300b from the atmosphere of the vaporized particles 600. This prevents the vaporized particles 600 from directly reaching the outer surfaces of the hollow cylindrical members 300b, which eventually prevents the ITO film 601 from being continuously formed from the insulated substrate 202 to the feed rollers 38.

According to the present embodiment, the hollow cylindrical members 300a separate the atmosphere of the vaporized particles 600 from the outer surfaces of the hollow cylindrical members 300b, to form a labyrinth in the path of migration and attachment of the vaporized particles 600. As a result, the ITO film 601 is not continuously formed from the insulated substrate 202 to the feed rollers 38, and hence the insulated substrate 202 can be maintained in a stable floated state to prevent the occurrence of an abnormal discharge. Further, the axles of the feed rollers 38 are no longer required to be formed of a ceramic material, but can be formed of a metal higher in rigidity, and hence it is possible to make the feed rollers 38 durable.

In the above described embodiment, the hollow cylindrical members 300b can be replaced by solid cylindrical members. Further, when a non-conductive film (e.g. SiO₂ or TiO₂) is formed on the insulated substrate 202, the support members 300 may be formed by the hollow cylindrical members 300b alone. Further, the number of the protrusions 201d may be 3, or more than 4.

Further, as shown in FIG. 7, the labyrinth may be formed in a path of migration and attachment of the vaporized particles 600 by a parallel board 700 which is arranged in parallel with the feeding direction A indicated in FIG. 2, such that the parallel board 700 separates the atmosphere of vaporized particles 600 from an outer surface of a parallel board 701 which is arranged in parallel with the parallel board 700 and higher than the parallel board 700. It is desirable that the parallel boards 700 and 701 extend over a length corresponding to one side of the tray 201 parallel to the feeding direction A.

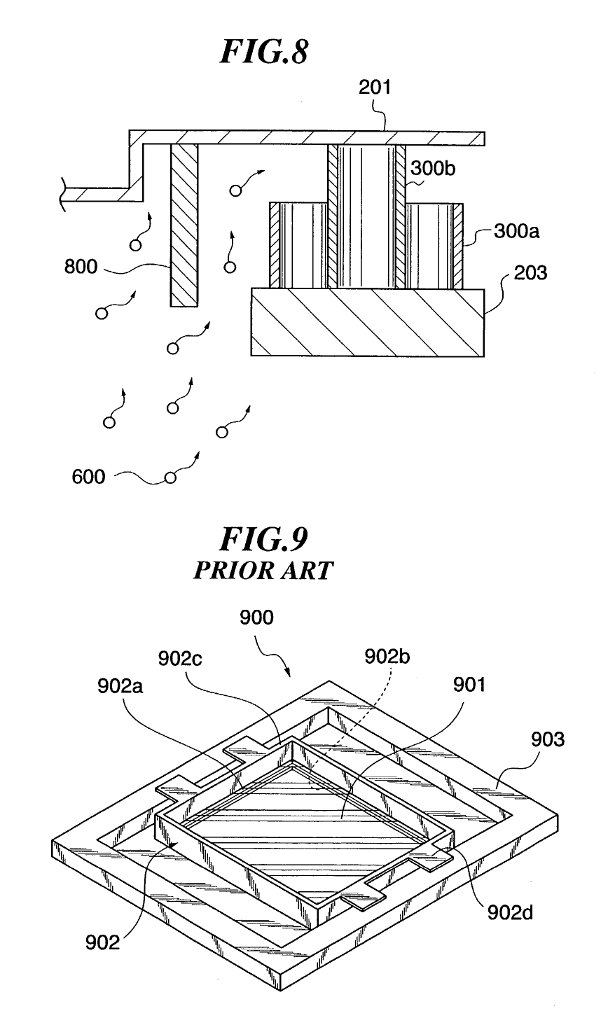

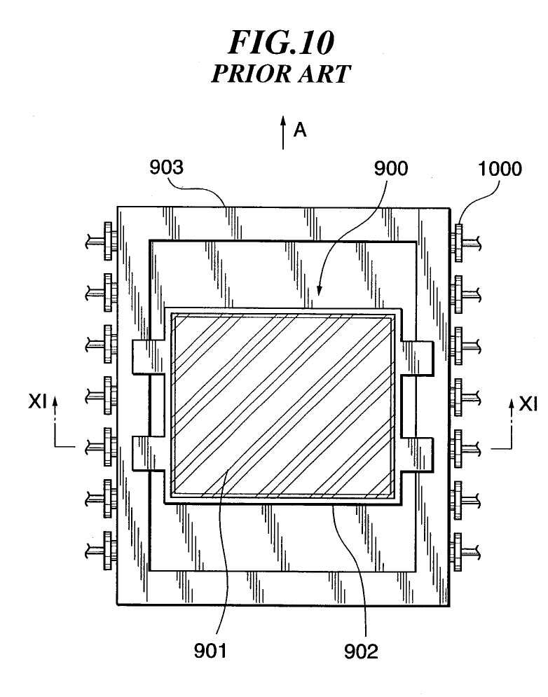

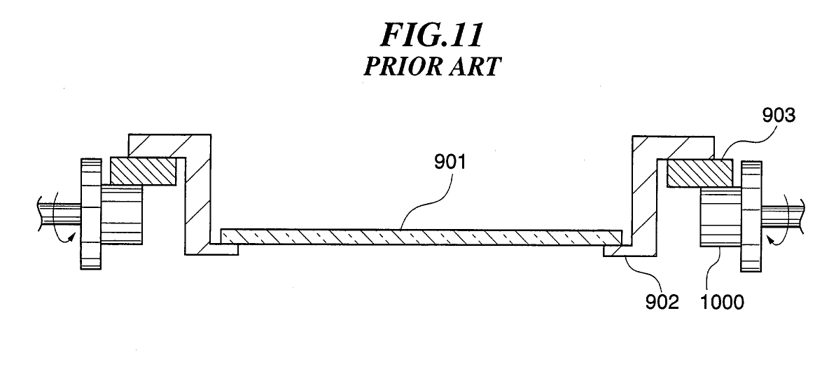

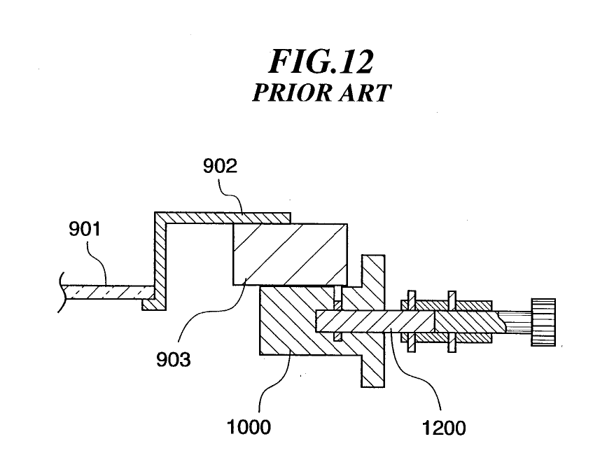

Also, as shown in FIG. 8, the labyrinth may be formed in a path of migration and attachment of the vaporized particles 600 by a flange 800 extending vertically from a surface of the tray 201 exposed to the atmosphere of the vaporized particles 600, and at the same time in parallel with the feeding direction A indicated in FIG. 2, such that the flange 800 and the hollow cylindrical members 300a separate the atmosphere of vaporized particles 600 from outer surfaces of the hollow cylindrical members 300b. It is desirable that the flange 800 extends over a length corresponding to the one side of the tray 201 parallel to the feeding direction A.

Next, examples of the present invention will be described in detail.

By using the FIG. 1 apparatus, test pieces of the substrate with a transparent conductive film were prepared by setting the aforementioned height A and angle θ as shown in Table 1. (Examples 1 to 6, and Comparative Examples 1 to 4)

TABLE 1

| | A: difference | | Percentage of occurrence |
|---|---|---|---|
| | in height | θ: Angle | of abnormal discharge |
| | (mm) | (°) | (%) |
| Example | | | |
| 1 | 2 | 45 | 0 |
| 2 | 2 | 60 | 0 |
| 3 | 5 | 45 | 0 |
| 4 | 5 | 60 | 0 |
| 5 | 10 | 45 | 0 |
| 6 | 10 | 60 | 0 |
| Comparative | | | |
| example | | | |
| 1 | 2 | 40 | 8 |
| 2 | 5 | 40 | 13 |
| 3 | 10 | 40 | 29 |
| 4 | 0 | 60 | 52 |

It should be noted that each hollow cylindrical member 300a was configured to have an outer diameter of 20 mm, a thickness of 1 mm, and a height of 5 mm. On the other hand, each hollow cylindrical member 300b was configured such that the difference A in height and the angle θ defined with respect to the hollow cylindrical member 300a were set to values shown in Table 1. Further, the material from which the hollow cylindrical members 300a and 300b were made was alumina (aluminum oxide).

Further, when the test pieces were prepared, an ITO sintered body having a SnO₂ content of 5.0 mass % was used as a tablet, and under the following discharge conditions, an ITO film 601 having a thickness of 150 nm was formed on the insulated substrate 202 by the ion plating method.

Discharge conditions

Discharge gas: Ar+O₂

Discharge current: 200 A

Pressure within vacuum container 8: 2.66×10⁻¹ Pa

(2.0×10⁻³ Torr)

Partial pressure of oxygen gas: 2.66×10⁻² Pa

(2.0×10^{31 4} Torr)

Temperature of insulated substrate 202: 200° C.

Then, the percentage of occurrence of marks caused by impulse of the abnormal discharge was measured concerning the above pieces. Results of the measurement are also shown in Table 1.

As is clear from Table 1, in Comparative Examples 1 to 3, the angle θ is set to the small value of 40°, so that the difference B in radius in FIG. 5 becomes large. Therefore, it is easy for the vaporized particles 600 to migrate into the inside of the hollow cylindrical member 300a. Consequently, a portion of the ITO film 601 is also formed between the hollow cylindrical member 300b and the hollow cylindrical member 300a so that the insulated substrate 202 and the feed rollers 38 are connected with each other by the ITO film 601. This causes an abnormal discharge to occur, which has been confirmed by the above measurement.

Further, in Comparative Example 4, the difference A in height is set to 0 mm, and hence a portion of the ITO film 601 is formed on the outer surfaces of the hollow cylindrical members 300a to such an extent that the insulated substrate 202 is connected to the feed rollers 38 via the portion of the ITO film 601 formed on the outer surfaces of the hollow cylindrical members 300a. This causes an abnormal discharge to occur, which has been confirmed by the above measurement.

In contrast, in Examples 1 to 6, the angle θ is set to values within the range of 45 to 60°, which are larger than the value employed in Comparative Examples 1 to 3, so that the difference B in radius becomes small. Therefore, it is difficult for the vaporized particles 600 to migrate into the inside of the hollow cylindrical member 300a. Consequently, the hollow cylindrical member 300b and the hollow cylindrical member 300a are not connected by a portion of the ITO film 601. Further, in Examples 1 to 6, the difference A in height is set to 2 mm and more, which are larger than 0 mm, a portion of the ITO film 601 formed on the outer surfaces of the hollow cylindrical member 601 does not connect between the insulated substrate 202 and the feed rollers 38. This prevents occurrence of an abnormal discharge, which has been confirmed by the above measurement.

Although in the above embodiment, as the material of the hollow cylindrical members 300a and 300b, alumina is employed, this is not limitative, but any of calcia, magnesia, quartz glass, thoria, titania, mullite, spinel, forsterite, zirconia, and zircon may be employed.

### INDUSTRIAL APPLICABILITY

According to the apparatus for manufacturing a substrate with a transparent conductive film of the present invention, second carrier means arranged on first carrier means and supporting a holding member for holding a substrate is comprised of a separator element and a support element, and the separator element forms together with the support element a labyrinth in a path of migration and attachment of vaporized particles to a surface of the support element. Therefore, it is possible to prevent occurrence of an abnormal discharge during formation of the transparent conductive film and make feed rollers as feeding means for the first carrier means durable.

What is claimed is:

1. An apparatus for manufacturing a substrate with a transparent conductive film, comprising:
a holding member for holding an insulated substrate;
first carrier means for supporting said holding member;
feeding means for feeding said first carrier means; and
second carrier means having at least one support element arranged on said first carrier member, and at least one separator element arranged on said first carrier member and extending along said support element;
wherein said first carrier member supports said holding member via said second carrier member, and said separator element forms together with said support element a labyrinth in a path of migration and attachment of vaporized particles for forming the transparent conductive film to a surface of said support element.

2. An apparatus for manufacturing a substrate with a transparent conductive film, comprising:
a holding member for holding an insulated substrate;
first carrier means for supporting said holding member;
feeding means for feeding said first carrier means; and
second carrier means having at least one support element arranged on said first carrier member, and at least one separator element arranged on said first carrier member and extending along said support element;
wherein said first carrier member supports said holding member via said support element of said second carrier means, and said separator element is lower in height than said support element such that said separator element partially separates said support element from an atmosphere of vaporized particles for forming the transparent conductive film within the apparatus.

3. An apparatus according to claim 2, wherein, in a right-angled triangle defined by a first side on said first carrier means, said first side corresponding to a distance between a surface of said support element facing toward said separator element and a surface of said separator element facing toward said support element, and a second side on the surface of said separator element corresponding to a height of said separator element, with said first side and said second side intersecting at right angles, an angle formed by a hypotenuse of said right-angled triangle and said first side is within a range of 45 to 85°.

4. An apparatus according to claim 3, wherein the angle is within a range of 60 to 85°.

5. An apparatus according to any one of claims 2 to 4, wherein a difference in height between said support element and said separator element is within a range of 1 to 5 mm.

6. An apparatus according to claim 5, wherein the difference in height is within a range of 1 to 3 mm.

7. An apparatus according to any one of claims 2 to 6, wherein said second carrier means is made of a ceramic material.

8. An apparatus according to any one of claims 2 to 7, wherein said support element and said separator element each comprise a hollow cylindrical member.

9. An apparatus according to claim 2, wherein said second carrier means comprises a plurality of pairs of said support element and said separator element arranged on said first carrier means.

10. An apparatus according to claim 2, wherein said support element and said separator element comprise boards arranged on said first carrier means.

11. An apparatus according to claim 10, wherein said boards extend along a whole length of an associated side of said holding member.

12. An apparatus according to claim 2, further comprising an additional flange-like separator element formed on said holding member
